(19) United States
(12) Patent Application Publication
(10) Pub. No.: US 2024/0348744 A1
(43) Pub. Date: Oct. 17, 2024

(54) RECEPTION AND SAMPLE RATE CONVERSION OF ASYNCHRONOUSLY TRANSMITTED AUDIO AND VIDEO DATA

(71) Applicant: Marc BRUNKE, Graz (AT)

(72) Inventor: Marc BRUNKE, Graz (AT)

(21) Appl. No.: 18/293,730

(22) PCT Filed: Aug. 1, 2022
(86) PCT No.: PCT/EP2022/071594

§ 371 Date: Jan. 30, 2024

(30) Foreign Application Priority Data
Aug. 3, 2021 (DE) 10 2021 120 204.3

(51) Int. Cl. H04N 7/01

(52) U.S. Cl. CPC H04N 7/0102

(57) ABSTRACT

The invention relates to methods for the conversion of data, which comprises at least the following steps. A number of asynchronously incoming data packets (P0, P1 . . . . P4) is received, wherein the data packets (DP) comprise input data (ED) with a first sample rate. The input data (ED) are assigned to positions in a filter buffer (22) based on the first sample rate. The input data (ED) are combined in the filter buffer (22) based on their respective position to form output data (SKD) with a defined second sample rate (SR2) in in course of a low-pass filtering (23). In the process the input data advance in the filter buffer (22) on a position-by-position and data-driven basis. The invention further relates to a conversion device (20) and a system (30) for the transmission of data as well as to the use of a filter buffer (22) in a conversion device (20) for the conversion of sample rates (SR1, SR2).

The invention relates to a method and a device for the conversion of data as well as a system for the transmission of data.

During the transmission of audio or video data between a sender (source) and a receiver (sink) the information is transmitted by wired or wireless means. The sender/the source may for example be a microphone, camera, DVD player or the like and the receiver/sink may be a loudspeaker, computer screen or the like. Frequently, the data is sent by means of known standards (e.g. DVI, HDMI, SPDIF, AES/EBU) along a direct route/by means of a point-to-point connection. Of late, it has become increasingly desirable to transmit this data via networks (e.g. Ethernet, Internet) because the network for example already exists or because many sources with many sinks are to form a network.

In order to establish compatibility between different or not synchronised sample rates (frame rates), the receiver processes the received data with the aid of an SRC (sample rate converter, frame rate converter). For example the SRC converts a received video signal with a first resolution into another resolution of the screen (e.g. source is 800×600 pixels, screen is 1920×1200 pixels) or in case of an audio signal into another sample rate (e.g. source with 48 KHz, loudspeaker with 44.1 KHz or 48 KHz if not synchronised with the source). An SRC is frequently realised with low-pass filters, which calculate based on the input signal, which pixels or samples are best suited for the new resolutions so that the viewer or listener can view or listen to a result, which is as true as possible compared to the source.

As digitisation progresses a new problem has come to the fore, i.e. latency. More and more systems must or can store data temporarily for various reasons. In networks for example latency arises in that: packets are dispatched, packets are reassembled, packets are delayed due to collisions, lost packets are requested again. Digital filters such as an SRC needed a number of frames or audio samples (in the following also abbreviated to samples) in order to optimise calculation of the new data. In particular, in the case of real time applications, where camera signals and/or microphone signals are transmitted directly to an audience, i.e. a spectator, views/listens to a live source, which is also simultaneously reproduced via screens and/or loudspeakers, noticeable delays frequently occur-a few milliseconds are already distinctly visible and in particular audible.

In order to convert the sample rate of transmitted data, synchronous point-to-point connections (e.g. DVI, SPDIF) are known on the one hand, in which a synchronisation signal/clock signal is transmitted together with the data. As a result, there is a known fixed relationship between the sample rates relative to each other, so that it is possible to perform a conversion with relatively easy means. Up to now, commonly known SRCs have operated based on this principle.

On the other hand it is also known from practice to convert the sample rate of data transmitted packet by packet and asynchronously in a network. To this end a relatively large input buffer is initially used in order to buffer and/or sort the incoming packets. The network is also used to dispatch synchronisation data, from which a synchronisation signal is reconstructed by means of a further electronic component. It is only then that actual conversion of the sample rate of the pre-buffered data takes place, wherein here again, due to the reconstructed synchronisation signal as above, a commonly known SRC is used in the main. With this principle of sample rate conversion therefore at least three components are required, namely an input buffer, a unit for reconstruction of the synchronisation signal and the actual SRC. Since the data is temporarily stored both in the input buffer and in the SRC for the respective processing step, the times required respectively for processing and thus the latencies mount up.

It is therefore an objective of the present invention, to propose an alternative data conversion for asynchronously incoming data packets, with which the above described latencies are reduced.

This objective is solven by a method for conversion according to patent claim 1, a conversion device according to patent claim 11, a system according to patent claim 12 and a use according to patent claim 13.

The method for the conversion of data mentioned in the beginning comprises at least the following steps. In one step the number of asynchronously incoming data packets is received. The data packets comprise input data with a first sample rate. In a further step the input data is assigned based on the first sample rate to positions in a combined input and filter buffer, in the following simply called “filter buffer”. The input data are combined based on their relative position in the filter buffer as part of a low-pass filtering process to form output data with a defined second sample rate. The input data advance in the filter buffer on a position-by-position and data-driven basis.

The expression “conversion” in terms of the invention is understood to mean a conversion of data. In particular, the conversion of data on the one hand relates to the conversion of packet-wise incoming data into a serial and preferably synchronisable/synchronised data stream and/or on the other hand to a change in the sample rate underlying the data.

The in particular digital data may comprise in principle any data, which have an underlying sample rate. They therefore generally may comprise a number of measuring points with associated measured values, the so-called samples. For example, the data may be present in the form of digital audio and/or video data, as will be explained in more detail further below.

In terms of the present invention a sample rate means a temporal or spatial resolution, which is underlying the data. I.e. the sample rate is inversely proportional to a temporal or spatial distance, which lies between individual measuring points. The data are thus recorded/measured at a respective sample rate and may also be stored, buffered, output and/or reproduced at this rate or also, after conversion, at another sample rate.

The incoming data, that is the input data, are received as a number of data packets for example by means of an input interface. One data packet in particular comprises at least one sample. Preferably one data packet comprises several samples. One data packet therefore is a so-called burst/data burst. In particular, a plurality/a series of, i.e. several, data packets are received. The input data therefore are asynchronous data incoming in the form of packets. The incoming data/data packets therefore are not synchronous, i.e. they are not coordinated in terms of timing and normally arrive at irregular intervals. However these data divided into packets always still have a sample rate, namely a first sample rate, underlying them.

Apart from the actual user data/the samples the data packets may also comprise, depending upon the respectively used transmission standard, further data such as header data. They may for example be data packets, which are transmitted over a network with a corresponding transmission protocol/network protocol. The network protocol may for example be a protocol from the group of TCP/IP protocols, in particular the Ethernet protocol or another commonly used internet protocol (IP) such as Sonet, ATM, 5G or the like. The data packets may take different paths in the network and thus also have different transmission times.

A position in the filter buffer has a filter tap assigned to it. It affects the result of the combination of the data present in the filter buffer forming the output data. This is done e.g. by means of a specifically defined weighting of the position/the filter tap in terms of the basically known low-pass filtering. Low-pass filtering may be implemented in various ways as will be explained in detail further below.

Newly incoming data—e.g. from the network—are assigned an initial position in the filter buffer, as will be described further below.

“Data-driven” means that when new data arrives, data already in the filter buffer advance by position. I.e., when no new data arrive, those already in the filter buffer remain in their current position. That is to say that the data advance in particular burst-driven, when a new data packet arrives. In contrast to the state of the art the filter buffer is not operated at a fixed or defined clock rate, which orients itself up to now on the first sample rate identified of necessity for this purpose, for according to the invention the positions of the data in the filter buffer only change when new data arrives. A determination of the first sample rate by means of the invention is thus in principle no longer necessary.

In particular, the data arrive at the same clock rate. Advancement of data takes place e.g. by moving the actual position of the samples in the buffer, by re-assigning the samples to virtual positions/taps with the aid of memory addresses, pointers or in a similar manner.

Consequently, as a position of a sample changes, the effect, e.g. the weighting during low-pass filtering of this sample during combination to form the output data, also changes. When a sample has passed through the envisaged positions in the filter buffer, it is deleted. As a result, space is created for the samples/data arriving thereafter.

The filter buffer in principle is a memory in particular a random memory, which can be read from and written to. The memory therefore does not have to be read from sequentially or in blocks. Preferably, addressing does not take place via individual cells but via words, i.e. in the form of blocks the size of a sample. It is filled as described with the input data and is read from at least in terms of low-pass filtering. In particular, it is implemented as an integrated circuit. However, it may also be composed of e.g. several memory modules.

Filtering takes place using in particular the entire filter buffer. This is based on the observation that the more data are used for filtering the better the result will be. This also means, in particular, that preferably no areas in the filter buffer remain unused.

After combining the data, a value is present for a sample of output data. I.e. by means of low-pass filtering a value is interpolated for each sample of the output data. Then, in order to generate output data at the second sample rate, the result of the combination/the low-pass filtering is read out/output at/with the clock rate of the second sample rate.

In principle, the second sample rate may be different from or equal to the first sample rate. Preferably, the second sample rate is different from the first sample rate. The second sample rate is defined/pre-set. I.e. it may for example be fixed when designing the method/the conversion device. Preferably, the second sample rate is adjustable. I.e. it may e.g. be defined/pre-set by means of a user input, in accordance with further devices connected to the conversion device or by means of a default setting.

Due to a preferably large-size design of the filter-buffer missing data packets and/or a wrong sequence of incoming data packets may be advantageously balanced without prior sorting as part of the conversion of the data. Moreover, with the inventive method it is advantageously no longer necessary, to reconstruct a synchronisation signal (sync signal). In particular, the inventive method is performed without reconstructing a synchronisation signal.

The conversion device for the conversion of data mentioned in the beginning comprises an input interface. The input interface is designed for receiving a number of asynchronously incoming data packets. The data packets comprise input data with a first sample rate. The conversion device also comprises a filter buffer. The filter buffer is designed such that input data in it is assigned to positions based on the first sample rate. Moreover, the input data in the filter buffer advance on a position-by-position and data-driven basis. Further, the conversion device comprises a low-pass filter. The low-pass filter combines the input data based on their respective position in the filter buffer to form output data with the defined second sample rate.

In particular, the conversion device according to the invention is thus designed for performing an inventive method for data conversion.

The input interface is for example designed as a normal interface for the network standard used. The conversion device preferably also comprises an output interface for outputting the output data. The output interface is implemented, for example, as a normal interface for a desired audio standard/video standard. The term input interface/output interface however also comprises non-standardised, i.e. for example proprietary interface designs.

In further contrast to the state of the art, the inventive method and the inventive conversion device can operate in principle without an input buffer/with a pre-buffer of very small dimensions. I.e. in principle, the filter buffer is already sufficient on its own for converting the data according to the invention, so that with regard to the basic invention no further buffer is necessary.

The initially mentioned system for the transmission of data comprises an asynchronous data network and an inventive conversion device, wherein the conversion device receives and converts data packets from the data network.

In this context, the term “system” generally denotes the interaction between the explicitly mentioned components. However, the system may also comprise several further components such as e.g. further units for audio processing and/or video processing, which, in particular, are comprised by a synchronous audio network and/or video network. The conversion device thus functions in particular as an interface between an asynchronous network and a synchronous network and/or an asynchronous or synchronous terminal device.

According to the invention a data-driven filter buffer is used in a conversion device for converting sample rates.

A large part of the previously mentioned components of the conversion device, in particular the low-pass filter, can be implemented wholly or partially in the form of software modules in a processor of a corresponding control device. In this respect, the objective is also met by a corresponding computer program product with a computer program, which can be loaded directly into a memory device of the control device of the conversion device, with program sections, in order to execute all or at least a part of the steps of the inventive method, when the program is run in the control device. Such a computer program product may comprise, apart from the computer program, additional components such as documentation and/or additional components, also hardware components such as hardware keys (dongles etc.) for using the software.

For transporting to the control device and/or for storing on or in the control device a computer-readable medium, for example a memory stick, a hard disc or another transportable or fixedly installed data carrier may be used, on which the program sections of the computer program are stored, which can be read in and executed by a computer unit of the control device. To this end, the computer unit may e.g. comprise one or more interacting microprocessors or the like.

Further, particularly advantageous embodiments and further developments of the invention can be derived from the dependent claims as well as from the following description, wherein the independent claims of one claim category may also be further developed analogously to the dependent claims of another claim category, and in particular individual features of different embodiments may also be combined to form new embodiments.

The input data preferably comprise samples according to the first sample rate. The samples of the input data are then preferably assigned based on the first sample rate to a respective position in the filter buffer. Combination of the input data is preferably performed depending on the respective position of its samples in the filter buffer.

A sample is a signal digitised from an analogue signal, i.e. a measured value recorded and digitised at a time of measurement. The sample comprises a bit depth, which depends on the way in which the measured values are recorded.

The input data and the output data preferably comprise audio data and/or video data. Accordingly, the audio data is typically in the form of audio samples, which comprise an audio level with a bit depth of 8 bits, 16 bits, 20 bits, 32 bits or preferably 24 bits. The audio data is thus in particular audio data from the professional audio range.

A video sample exists for each video frame and for each video level/colour channel and the pixel assigned to this video level. Thus for example a video frame of an HD signal with 1080 lines and 4:2:2 colour resolution consists of 1920 samples for the Luma signal and respectively 960 samples for the two colour difference signals per line, i.e. of a total of 3840 samples per line. The inventive conversion can however be applied in principle to any spatial resolutions/colour resolutions as well as temporal resolutions. The colour depth is, for example, 24 bits (true colour, 8 bits each for R, G and B), 32 bits (true colour+8 bit alpha channel, 8 bits each for R, G, B and alpha), preferably 30 bits (deep colour/HDR video, 10 bits each for Y, U and V), especially preferably 36 bits (deep colour/HDR10+/Dolby vision, 12 bits each for R, G and B).

The first sample rate of a video signal has thus several components. A first component is the temporal resolution into individual video frames, i.e. the image refresh rate/frame rate.

One or more second components of the first sample rate of the video signal are the spatial resolutions of the individual colour channels. This applies analogously to the second sample rate. The second sample rate—as already described above—may be equal to the first sample rate, so that the conversion of packet-wise incoming data forms a serial data stream. However, it may also be different in one or more components from the first sample rate, so that these components are converted.

With video data, the inventive conversion method may be analogously applied to one or more components of the signal. That is it can be used for converting the image refresh rate and/or the spatial resolution of the individual colour channels. This means in particular that the principle of low-pass filtering can be applied to both the temporal sequence of samples, which have been assigned a pixel, and to video levels e.g. spatially adjacent pixels of a video frame, for example, in order to interpolate intermedia pixels for a higher spatial resolution. With a suitable memory in the filter buffer and sufficient computing performance simultaneous conversion of the image refresh frequency and spatial resolution is also possible.

The audio data preferably comprises sample rates of 44.1 KHz, 48 KHz, 88.2 kHz, 96 KHz, 176.4 kHz or 192 KHz. The video data preferably comprises temporal sample rates/frame rates of 25 Hz, 50 Hz, 59.94 Hz, 100 Hz, or 119.88 Hz.

The positions of the filter buffer preferably have filter coefficients assigned to them for low-pass filtering, which are especially preferably adjustable. In other words, the output data are generated from a linear combination from the data stored at the positions in course of the low-pass filtering, wherein the filter coefficients serve as weighting factors. The fact that the filter coefficients are “adjustable” means that they can be altered according to the requirement. If, for example, the first sample rate or the second sample rate, with which the output data is output, are altered, the filter coefficients can be adapted accordingly.

Low-pass filtering takes place preferably using an IIR filter or especially preferably using a FIR filter. Generally, the operating principles of the respective filters are known to the expert.

With an FIR filter, the data stored in the filter buffer can be modified especially preferably by means of feedback loops. Preferably, each position in the filter buffer/each filter tap has a feedback loop assigned to it. If, for example, it is determined during data read out that the data remains unchanged at one or more positions because, for example, no new input data is arriving, the respective feedback loop controls that the data stored at the position approaches the value of zero asymptotically. In other words, the feedback loops make sure in this case that the filter is gradually depleted.

As already mentioned previously, the output data is preferably generated as a serial data stream by repeating at least part of the steps of the inventive method. As part of the steps, the combination may for example be repeated; this causes a new sample of output data to be generated each time.

The combination can also be repeated in particular, when no new input data is received. In case the filter buffer is arranged such that the data remains unchanged in its position when new data fails to arrive, a temporally constant value may for example be output as output data when repeating the combination. Alternatively, however, it is also possible in this case to implement the above described gradually depletion by means of feedback loops.

In principal, the chance of balancing data, that got lost or arrived in the wrong order, is greater the more data is available for low-pass filtering. Therefore, the filter buffer is preferably dimensioned such that at least 5 ms, more preferably at least 10 ms, especially preferably at least 15 ms, most preferably 20 ms of input data can be buffered.

Under normal operating conditions, essentially all packets sent over the network are received as input data. This means that only very few packets are lost in the transmission, so that preferably even after a short time of samples arriving per time unit an average sample rate can be estimated, which essentially is equal to the first sample rate underlying the input data. Especially preferably, the first sample rate is estimated in that the rate is associated with incoming samples of one of the standard sample rates, in particular one of the above-named sample rates. However, this estimating does not mean a reconstruction of a sync signal/clock signal, as it would be required for an SRC of the state of the art.

The input data is preferably pre-buffered and especially preferably pre-sorted in a pre-buffer arranged upstream of the filter buffer. The pre-buffer is a memory, which is small in relation to the filter buffer. Preferably, the pre-buffer is smaller by a multiple relative to the filter buffer. I.e. it has a memory size of at most a third, preferably at most a fourth, especially preferably at most a fifth and most preferably at most a tenth of the memory size of the filter buffer.

The pre-buffer may for example be implemented as a FIFO memory. Especially preferably the pre-buffer comprises a logic, which sorts the data packets for example by way of header data, as is customary in many network protocols.

The pre-buffer is thus meant to temporarily store only a relatively small amount of data, in order, for example, to intercept bursts of data, i.e. one or more data packets arriving at short intervals one after the other. Between such bursts there are pauses in the transmission. They arise e.g. as a result of the combination of several samples within the source in order to send data packets more efficiently. The pre-buffer is thus a means of filling the filter buffer in a more even and orderly manner, which improves the result of the subsequent low-pass filtering. To this end, the pre-buffer is connected especially preferably with a logic, a circuit or an electronic component, which estimates the first sample rate as already described above. Furthermore, the pre-buffer preferably forwards the individual samples at a higher rate than the estimated sample rate. The rate is higher by preferable at least 1%, especially preferably by at least 2%, most preferably by at least 4% than the estimated sample rate. This preferably prevents the pre-buffer from overflowing.

The filter buffer is preferably designed such that it can be simultaneously read from and written to. Collisions, which may for example arise due to simultaneous accesses, are preferably handled by arbitration logic. It may thus be designed as e.g. a dual port RAM. This implementation of the filter buffer is particularly advantageous, as it allows the two otherwise separate systems to work with the shared data when filling and reading the filter buffer without restricting each other's access speed.

In the filter buffer the data advances at an average clock rate, which essentially—i.e. for example except for lost packets—is equal to the first sample rate.

In the conversion device, the filter buffer and the low-pass filter form an interpolator. The signal present at the output of the low-pass filter is updated at a high frequency, which e.g. lies in the range of 50 MHz. The conversion device preferably also comprises a decimator, which is arranged downstream of the interpolator and outputs the intermediate results generated by the interpolator at the desired second sample rate, i.e. at a lower frequency, the new video resolution or the desired audio sample rate respectively.

As previously described the input data are preferably converted into output data in form of a serial data stream. The serial data stream of output data is especially preferably synchronous/synchronisable with a number of devices connected to the conversion device. The output data is then preferably transmitted via an output interface to the number of further devices, with which the conversion device is synchronised. This may be merely one or also several devices synchronously connected to the conversion device. Especially preferably the conversion device is synchronously connected to a synchronously operating audio interface and/or video interface, which has the number of further devices arranged downstream of it.

By means of the invention the quality or the (low-pass) filter of the interpolator of the sample rate converter is thus improved by the distinctly increased number of taps. Further, due to the increased low-pass effect an increased tolerance is achieved for unstable or large networks. In addition, the three electronic components described in the beginning are implemented in only one component.

The invention is explained in more detail below with reference to the accompanying figures using exemplary embodiments. In the various figures, identical components are indicated by identical reference numerals. The figures are generally not to scale.

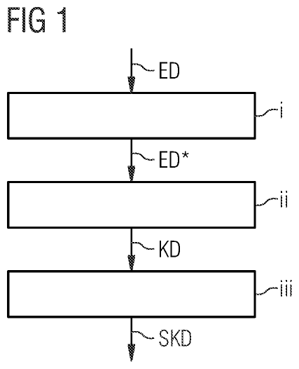

FIG. 1 shows a block diagram depicting a workflow of an inventive method for the conversion of data by way of an exemplary embodiment,

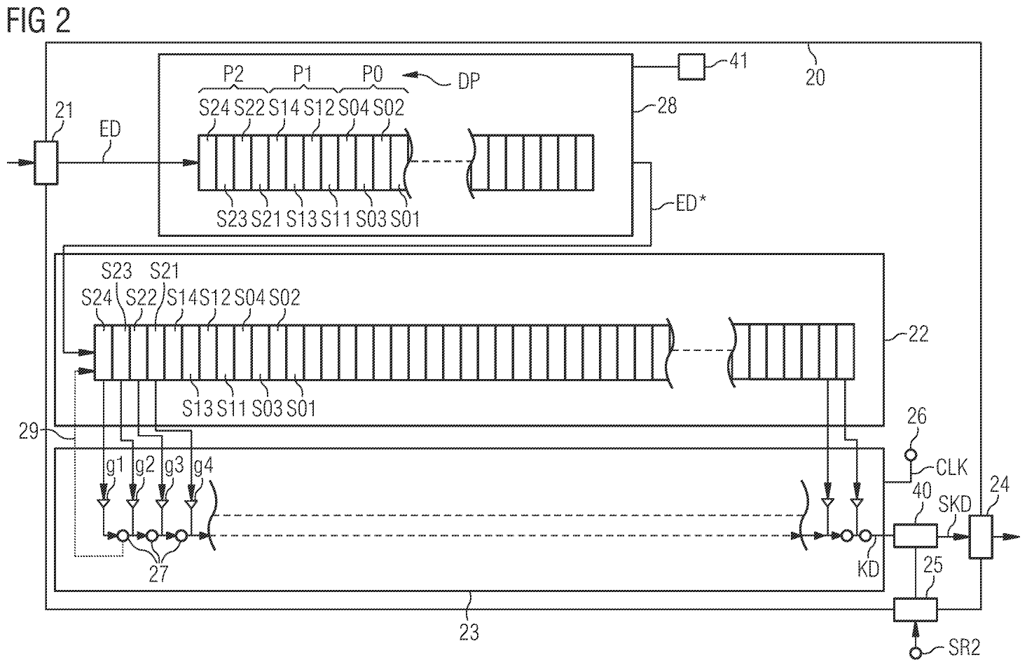

FIG. 2 shows a block diagram of an exemplary embodiment of an inventive conversion device for the conversion of data, and

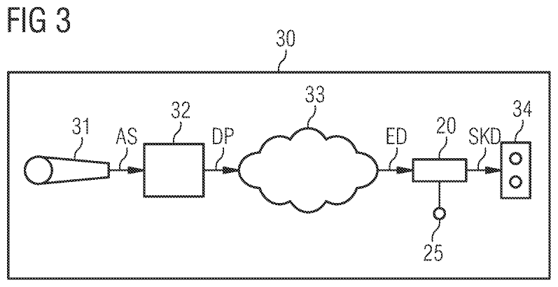

FIG. 3 shows a rough schematic diagram of an exemplary embodiment of an inventive system for the transmission of data.

FIG. 1 shows roughly schematically a block diagram of a sequence of an inventive method for the conversion of data. It is explained below together with the exemplary embodiment of a conversion device 20 according to the invention for the conversion of data shown schematically as a block diagram in FIG. 2.

In a first step i the asynchronously incoming input data ED are received in the form of data packets DP by means of an input interface 21. For simplicity's sake three data packets P0, P1, P2 are depicted by way of example. Normally however, the number of data packets DP is much larger. The data packets arrive asynchronously because they are received via e.g. a network and because their runtime through the network therefore differs due to differently arranged packets or differently routed paths through the network.

The input data ED comprise a plurality of samples S01, S02, . . . , S23, S24 etc., which are based on a first sample rate SR1. For ease of explanation, the reference symbol for a sample in the present example comprises behind the “S” as front digit the respective packet number and as rear digit the number of a sample in the respective packet. The input data ED represent e.g. a digitised audio signal, which was sampled at the first sample rate SR1 of e.g. 96 KHz and a bit depth of 24 bit. Each sample S01, S02, . . . , S23, S24 thus comprises a sample value, which characterises the audio signal. As long as the audio signal is recorded, digitised and transmitted, input data ED arrive at the input interface 21. Even if the data packets, P1, P2 for ease of depiction, are shown with only four samples respectively, it is clear that in a real application they comprise a consecutive number of samples, i.e. in course of the transmission a continuous series of audio/video samples, until the connection is terminated or faulty.

Optionally, the input data are temporarily buffered in a pre-buffer 28 in order to balance an irregular arrival of data packets DP, and further optionally pre-sorted by way of e.g. their head data to form sorted input data ED*. To this end, the pre-buffer 28 optionally comprises a sorting logic (not shown). If for example the data packet P1 would have arrived at the input interface 21 prior to the data packet P0, they could be pre-sorted in the pre-buffer 28, so that they are again arranged in the depicted correct order. To this end, the pre-buffer may be designed e.g. as a FIFO buffer.

Preferably, the pre-buffer 28 is connected to an estimating logic 41. The estimating logic 41 estimates the first sample rate SR1 based on the rate of the incoming samples S01, S02, . . . , S23, S24. This is done, for example, by assigning the rate of the incoming samples S01, S02, . . . , S23, S24 to a standard audio sample rate, for example 44.1 KHz, 48 KHz, 88.2 kHz, 96 KHz, 176.4 kHz or 192 KHz.

The pre-buffered/sorted input data ED* is transferred preferably sample-wise, into a filter buffer 22 at a higher rate than the estimated sample rate. That is, each sample S01, S02, . . . , S23, S24 etc. is stored at a position/in a filter tap in the filter buffer 22. For ease of depiction, the positions here are shown in a consecutive series. Even if such an implementation is possible in principle, it will nevertheless be clear to the expert that in a memory the position is frequently described e.g. by memory addresses or pointers. Accordingly, the samples S01, S02, . . . , S23, S24 as a rule need not be stored at memory locations that are actually in a sequence, but the ordered series of samples S01, S02, . . . , S23, S24 may be understood as a series of memory addresses/pointers assigned to the samples S01, S02, . . . , S23, S24.

When new input data ED arrive/when new data are transferred into the filter buffer 22, the samples S01, S02, . . . , S23, S24 in the filter buffer advance in a data-driven manner position-by-position. I.e. the position of samples S01, S02, . . . , S23, S24 is shifted by the number of newly arriving samples. As described above, this can take place in principle via an actual movement of the sample to a new memory location. Preferably, the series of memory addresses/pointers is simply changed accordingly.

A weighting element g1, g2, . . . , gn of a low-pass filter 23 is assigned to each position/filter tap in the filter buffer 22. That is, as part of a low-pass filtering process performed in step ii of the method the values of samples S01, S02, . . . , S23, S24 are each weighted by means the weighting element/by means of the filter coefficient g1, g2, . . . , gn, which is assigned to them based on their position in the filter buffer 22.

Subsequently, the correspondingly weighted values are all added together by means of a summing element 27. In other words, in the low-pass filter 23 a linear combination is generated from the samples S01, S02, . . . , S23, S24, which reproduces the underlying audio signal as true to the original as possible. I.e. the weighting elements/the filter coefficients g1, g2, . . . , gn are ascertained and set for defined relationships between the sample rates SR1 and SR2 in dependence of the number of used filter taps. The setting of the filter coefficients may be fixed for certain parameters during production, for example, or may also be set electronically at a later stage. The result of this linear combination is output as combined data KD by the low-pass filter 23.

The filter buffer 22 is shown here as a FIR filter, which permits differentiated control. However, it may just as well be implemented e.g. as an IIR filter, which advantageously requires few logic components and can therefore be implemented in a compact and simple manner. Empty samples/“zeros” can be fed into the filter buffer by means of a simple idling logic 29, as soon it is determined that no new input data arrive within a defined time span. Alternatively or additionally feedback loops (not shown here) may be formed in a similar manner for all positions in the filter buffer 22, which under predetermined conditions may modify the values of the samples S01, S02, . . . , S23, S24 in the filter buffer 22. To this end, the filter buffer 22 may e.g. be designed as a dual port RAM, which advantageously permits simultaneous reading or writing access from two sides, for example by both feeding into or advancing in the filter buffer 22 as well as the feedback loops.

Evaluation of the filter buffer 22 by means of the low-pass filter 23 and the output of the combined data KD is preferably performed at a second sample rate SR2. The second sample rate SR2 is defined in the sense that it is adjustable and can, for example, be pre-set via an input interface 25. Here, “Pre-set” means e.g. that a user selects and inputs the second sample rate SR2, that the second sample rate SR2 is pre-set via a connection to other units interacting with the conversion device 20 or via a network, that the second sample rate SR2 is pre-set as default value, or the like.

Reading of the filter buffer 22 by means of the low-pass filter 23/the low-pass filtering process is preferably performed in an already synchronised manner. I.e. a sync signal CLK is provided for synchronisation my means of a sync source 26. To this end, the sync source 26 can—as shown here—be arranged in the conversion device 20 so that other devices connected to the conversion device synchronise on this sync signal CLK. However, the sync source 26 may also be implemented as an interface to another device connected to the conversion device or as a network interface.

The converted data KD are transmitted to a decimator 40 at a high frequency of for example 50 MHz. From the high-frequency intermediate results generated in this way the decimator 40 again generates data at a lower frequency, namely at the desired second sample rate SR2, i.e. the desired video resolution or the desired audio sample rate, and thus converts the data in step iii into sample-rate-converted data SKD.

The second sample rate SR2 may thus be set/specified by e.g. a user input or by means of a signal, which e.g. was transmitted from a connected synchronous device or network.

The sample-rate-converted data SKD are output by means of an output interface 24. The output interface 24 may e.g. have further, preferably synchronised, devices or a network connected to it.

Alternatively, the pre-buffer 28 may be designed also as a FIFO buffer in a simple manner, i.e. without any sorting being implemented in it. In this case, it is merely ensures that the filter buffer 22 is filled more evenly with the input data ED in order to compensate for irregular arrival of the data packets DP such as e.g. any bursts or pauses. Furthermore, alternatively, the input data ED can also be directly assigned to positions in the filter buffer 22 without pre-buffering. In this case, the conversion device 20 also does not comprise a pre-buffer 28.

The filter buffer 22 is implemented much larger than the pre-buffer 28. As already depicted by the range interruptions in FIG. 2, not all positions of the pre-buffer 28 and the filter buffer 22 are shown. Equally, the relationship between the pre-buffer 28 and the filter buffer is not shown to scale, rather the filter buffer 22 is preferably many times larger than the pre-buffer 28. It is dimensioned to buffer in particular at least 5 ms, preferably at least 10 ms, especially preferably at least 15 ms, most preferably at least 20 ms of the input data ED. Due to this size of filter buffer 22 it is advantageously easier to compensate for mixed-up and/or missing data packets DP—in particular if there is no pre-buffer 28 or if the pre-buffer 28 on its own is not sufficient.

If for example the samples S01, S02, S03 and S04 of the first data packet P0 had failed, the samples S11, S12, S13 and S14 of the second data packet P1 would directly follow the previous data. This could possibly cause a break/crackling in the audio signal, if the signal were output without further ado. However, since a very large number of additional samples are taken into account during low-pass filtering, the missing first data packet P0 is no longer of significant importance for normal human hearing. The same applies analogously in the event that, e.g., the first data packet P0 and the second data packet P1 reach the filter buffer 22 in wrong order.

In the description of FIG. 2, it was stated as an example at the beginning that the first sample rate SR1 is 96 KHz. If the input data in another example comprises a first sample rate SR1 of only 48 KHz, the parameters such as e.g. the filter coefficients g1, g2, . . . , gn can be modified in order to output the signal so that it is as close as possible to the original at the second sample rate SR2.

The weighting factors of the weighting elements g1, g2, . . . , gn can also preferably be set. They may, for example, be determined dependent on the (estimated) first sample rate SR1, the second sample rate SR2 and/or other relevant parameters.

Due to the inventive conversion device/the inventive method for conversion, latency can be advantageously reduced in comparison to previously known SRC devices, which operate with asynchronously arriving data packets. This is because with previous solutions, the latencies of the input buffer which is large in relation to the invention, (latency e.g. 4 ms for 192 samples with 48 KHz) and is required to reconstruct a sync signal, and of the actual SRC (latency e.g. 4 ms for 192 samples with 48 kHz), whose latency is substantially dominated by the latency of the interpolator (total latency thus 8 ms), add up. The latency generated by the input buffer may be completely avoided or at least substantially reduced by means of the present invention (latency in total e.g. 4 ms for 192 samples for 48 KHz). A reconstruction of a sync signal is advantageously no longer required.

FIG. 3 shows roughly schematically a diagram of an embodiment of a system 30 according to the invention for the transmission of data. The system 30 comprises a microphone 31 as audio source, the audio signal AS of which is pre-amplified and digitised by means of an A/D converter, i.e. is sampled with the first sample rate SR1 and a defined bit depth. The sampled signal is transmitted to a network device 32, packed there into data packets DP and transmitted by means of a defined network protocol, e.g. Ethernet or other customary internet protocols (IP) such as Sonet, ATM, 5G, over a data network 33. In the data network 33, the data packets DP can be routed differently and are therefore received asynchronously by the conversion device 20 as input data ED.

The conversion device 20 converts the input data ED, in particular, the data is converted into synchronised data and/or sample-rate-converted data SKD. For a conversion of the sample rate, a second sample rate SR2 to be output may be set by means of an input interface 25. This setting may be performed e.g. by a user, by a connected audio device or also via the data network 33 or also via an audio network synchronously connected to the conversion device 20.

The synchronous and sample rate-converted data SKD is converted back into an analog audio signal and played back using a suitable loudspeaker 34 . . . . In addition to the microphone 31 and the loudspeaker 34 the system may also comprise a plurality of further audio sources (microphones, Line-IN etc.), play-back devices, processing devices (such as mixing consoles), or network devices (such as routers, repeaters) and/or the like.

The conversion device 20 according to the invention is thus used as an interface between an asynchronous data network 33 and synchronised audio devices such as loudspeakers 34, and/or synchronous data networks, in particular synchronous audio networks and/or video networks.

In conclusion, it is pointed out once more that the devices described above in detail are merely exemplary embodiments, which the skilled person can modify in the various ways without leaving the scope of the invention. Although the exemplary embodiment was explained merely by way of audio data, the inventive principle and in particular also the low-pass filtering process by means of two-dimensional or multi-dimensional arrays of samples can be easily applied to video signals/video data. Furthermore, the use of the indefinite article “a”/“one” does not exclude that the respective features may be present a number of times. Equally, the terms “device”, “unit” and “system” do not exclude that the respective component may consist of several interacting partial components, which, as the case may be, may also be spatially distributed.

### LIST OF REFERENCE SYMBOLS

20 conversion device
21 input interface
22 filter buffer
23 low-pass filter
24 output interface
25 input interface
26 sync source
27 summing element
28 pre-buffer
29 idling logic
30 system
31 microphone, audio source
32 network device
33 data network
34 loudspeaker
40 decimator
41 estimating logic
AS audio signal
CLK sync signal
DP data packets
ED input data
ED* sorted input data
g1, g2 . . . gn weighting element, filter coefficient
KD combined data
P0, P1, P2 data packets
S01, S02 . . . S23, S24 sample
SKD sample-rate-converted data
SR1 first sample rate
SR2 second sample rate
i, ii, iii method steps

1. A method for the conversion of data comprising at least the following steps:
a) receiving a number of asynchronously incoming data packets, said data packets comprising input data with a first sample rate,
b) assigning the input data to positions in a filter buffer based on a first sample rate,
c) combining the input data based on their respective position in the filter buffer to form output data with a defined second sample rate in course of a low-pass filtering, wherein the input data in the filter buffer advance on a position-by-position and data-driven basis.

2. The method according to claim 1, wherein
the input data comprise samples according to the first sample rate,
the samples of input data are assigned based on the first sample rate to respectively a position in the filter buffer, and
the combination of the input data is effected in dependence of the respective position of their samples in the filter buffer.

3. The method according to claim 1, wherein the input data and output data comprise audio data and/or video data.

4. The method according to claim 3, wherein the audio data comprise sample rates of 44.1 kHz, 48 kHz, 88.2 kHz, 96 kHz, 176.4 kHz or 192 KHz.

5. The method according to claim 3, wherein the video data comprise sample rates of 25 Hz, 50 Hz, 59.94 Hz, 100 Hz, or 119.88 Hz.

6. The method according to claim 1, wherein the positions of the filter buffer for low-pass filtering are assigned filter coefficients, which are adjustable.

7. The method according to claim 1, wherein low-pass-filtering is performed using an FIR filter.

8. The method according to claim 1, wherein the filter buffer is dimensioned to buffer at least 20 ms of the input data.

9. The method according to claim 1, wherein the input data, before entering the filter buffer, are temporarily buffered in a pre-buffer and pre-sorted, wherein the pre-buffer is smaller than the filter buffer.

10. The method according to claim 1, wherein the filter buffer is designed such that it can be simultaneously read from and written to.

11. A conversion device for the conversion of data comprising
an input interface, which is designed for receiving a number of asynchronously incoming data packets, wherein the data packets comprise input data with a first sample rate,
a filter buffer, which is designed such that the input data are assigned to positions in there based on the first sample rate and the input data advance on a position-by-position and data-driven basis, and
a low-pass filter, which combines the input data based on their respective position in the filter buffer to form output data with the defined second sample rate.

12. A system for the transmission of data with an asynchronous data network and a conversion device according to claim 11, wherein the conversion device receives and converts data packets from the data network.

13. A use of a data-driven filter buffer in a conversion device for the conversion of sample rates.

14. The method according to claim 1, wherein the positions of the filter buffer for low-pass filtering are assigned filter coefficients.

15. The method according to claim 1, wherein low-pass-filtering is performed using an IIR filter.

16. The method according to claim 1, wherein the filter buffer is dimensioned to buffer at least 5 ms of the input data.

17. The method according to claim 1, wherein the filter buffer is dimensioned to buffer at least 10 ms of the input data.

18. The method according to claim 1, wherein the filter buffer is dimensioned to buffer at least 15 ms of the input data.

19. The method according to claim 1, wherein the input data, before entering the filter buffer, are temporarily buffered in a pre-buffer, wherein the pre-buffer is smaller than the filter buffer.
